(19) United States
(12) Patent Application Publication
(10) Pub. No.: US 2008/0055868 A1
(43) Pub. Date: Mar. 6, 2008

(54) Cabled module, multi-processor system architecture

(76) Inventors: Eric C. Peterson, McKinney, TX (US); Mark Edward Shaw, Garland, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/511,602

(22) Filed: Aug. 29, 2006

(51) Int. Cl. H05K 5/00

(52) U.S. Cl. 361/752

(57) ABSTRACT

A multi-processor system architecture comprises: a cabinet; a plurality of processor cell modules disposed within the cabinet; a plurality of link router modules disposed within the cabinet; and a plurality of cables connecting the plurality of processor cell modules through the plurality of link router modules.

### BACKGROUND

Most multi-processor computer systems comprise a series of cell modules, each including one or more processing units, connected to a backplane or midplane to form the system architecture. Generally, the backplane or midplane is a printed circuit (PC) board with etched interconnecting routing and possibly, active components as well. Although, some backplanes and midplanes are passive. Also connected to the backplane or midplane in such systems are interconnecting modules, which may be implemented on PC boards, for example. The interconnecting modules generally contain switching elements for managing the communication among the cell modules of the system and for interfacing with input/output (IO) devices. This current system is very rigid in that it requires the architecture to be well designed prior to implementation. No flexibility is normally provided for changes to the system design that may occur during the development cycle or after product shipment. In addition, etched routing on a PC board has greater losses than cable, and thus, system components should be in close proximity to one another to perform at high speeds.

### SUMMARY

In accordance with one aspect of the present invention, a multi-processor system architecture comprises: a cabinet; a plurality of processor cell modules disposed within the cabinet; a plurality of link router modules disposed within the cabinet; and a plurality of cables connecting the plurality of processor cell modules through the plurality of link router modules.

### BRIEF DESCRIPTION OF THE DRAWINGS

FIG. 1 is an isometric perspective illustration of an exemplary embodiment of a cell board for use in a cell module.

FIG. 2 is an isometric perspective illustration of an exemplary embodiment of a cell module containing the cell board embodiment of FIG. 1.

FIG. 3 is an isometric perspective “see through” illustration of a cabinet rack enclosure containing two cell modules arranged side-by-side.

FIG. 3A is an isometric perspective illustration of a fully enclosed cabinet rack.

FIG. 4 is an isometric perspective view of the cabinet rack of FIG. 3 illustrating the convenience of assembly and disassembly of the various components thereof.

FIG. 5 is an isometric perspective illustration of an exemplary embodiment of a half link router module.

FIG. 6 is an isometric perspective illustration of an exemplary embodiment of a full link router module.

FIG. 7 is an isometric perspective illustration of a plurality of link router modules in a stair-step arrangement.

FIG. 8 is an isometric perspective “see through” rear view illustration of a cabinet enclosure suitable for embodying a cabled module, multi-processor system architecture.

FIG. 8A is an expanded isometric perspective “see through” rear view illustration of a bottom of the cabinet enclosure of FIG. 8.

FIG. 9 is an isometric perspective “see through” rear view illustration of a cabled module, multi-processor system architecture showing cables interconnecting cell modules through link router modules.

FIG. 9A is an expanded isometric perspective “see through” rear view illustration of a bottom of the system architecture of FIG. 9.

### DETAILED DESCRIPTION OF THE INVENTION

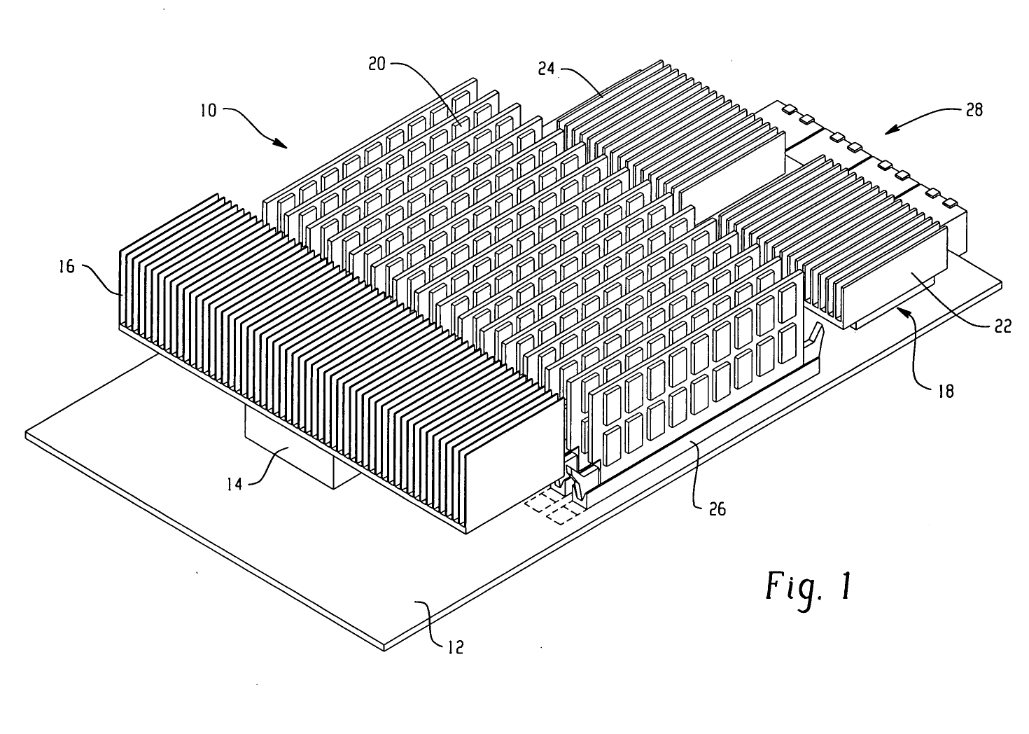

The present embodiment comprises a cabled module, multi-processor system architecture which overcomes the inflexibility to change of the current systems as will become more evident from the following description. An exemplary cell board 10 suitable for use in a cell module of the present embodiment is shown in the isometric perspective illustration of FIG. 1. Referring to FIG. 1, the cell board 10 comprises a printed circuit board 12 on which are mounted various cell elements including at least one processing unit 14, which may be a microprocessor integrated circuit (IC) or chip, for example. A heat sink 16 may be disposed on the processor IC 14 for protecting it against overheating. Other components which may be mounted on the board 12 include one or more processor agent ICs 18 and a plurality of memory modules 20.

In the present embodiment, the board 12 includes two processor agent ICs with each such IC having a corresponding heat sink 22 and 24 disposed thereon, and the plurality of memory modules 20 are comprised of sixteen (16) dual in-line memory modules or DIMMs which are each connected to the board 12 through a corresponding connector 26. While 16 DIMMs are used in the present embodiment, it is understood that the memory modules 20 may include other numbers of DIMMs just as well. At the rear of the board 12 is a set of connectors 28 which may comprise eight (8) high speed connectors which may be of the model type HMZD manufactured by Tyco™ or model type GVX manufactured by Molex™ or Paradyne™, for example. The board 12 includes etched routing for interconnecting the various components mounted thereon together and to the set of connectors 28.

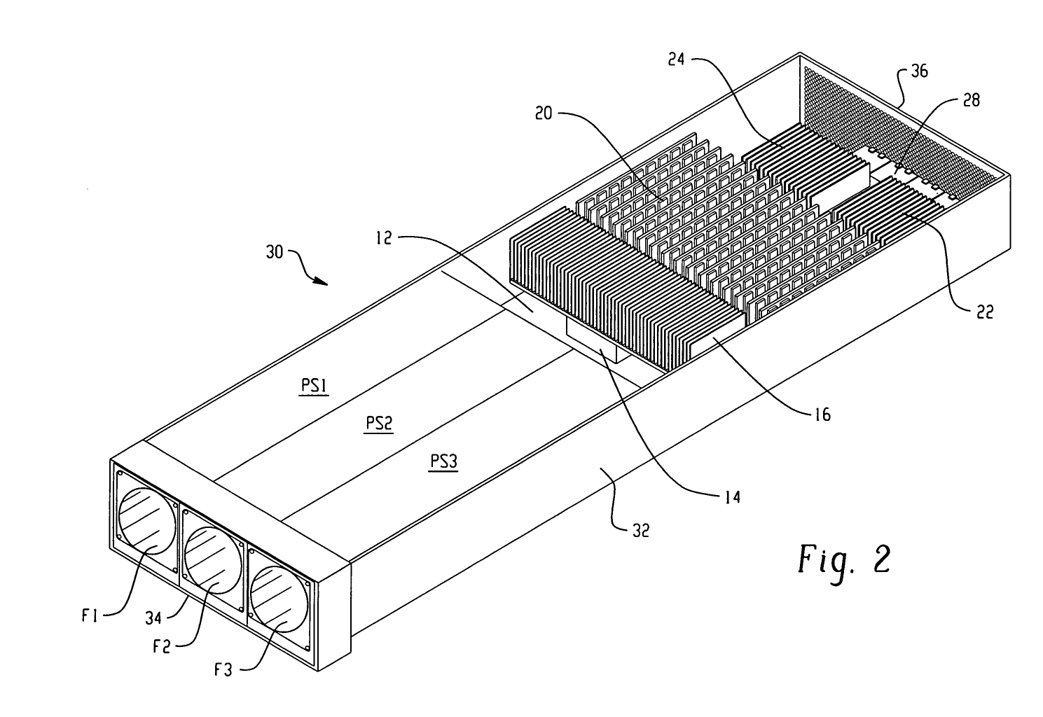

At least one cell board 10 may be disposed in a cell module 30 as shown in the isometric perspective illustration of FIG. 2. Referring to FIG. 2, the cell module 30 comprises a housing 32 into which the at least one cell board 10 is disposed. At the front 34 of housing 32 may be disposed a plurality of power supply modules for providing power to the at least one cell board 10. In the present embodiment, three (3) power supply modules PS1, PS2 and PS3 are slidably disposed side by side in housing 32. The modules PS1, PS2 and PS3 may be of the AC input type and may include an integrated cooling solution comprising a cooling fan F1, F2 and F3, respectively, situated at the front thereof. The other end 36 of housing 32 may be perforated to permit fan forced cooling air to flow across the cell board 10 and through the housing 32 to protect the cell components from overheating. The end 36 may also include an opening to permit cable connections to the set of connectors 28 of the cell board 10 as will become more evident from the description found herein below.

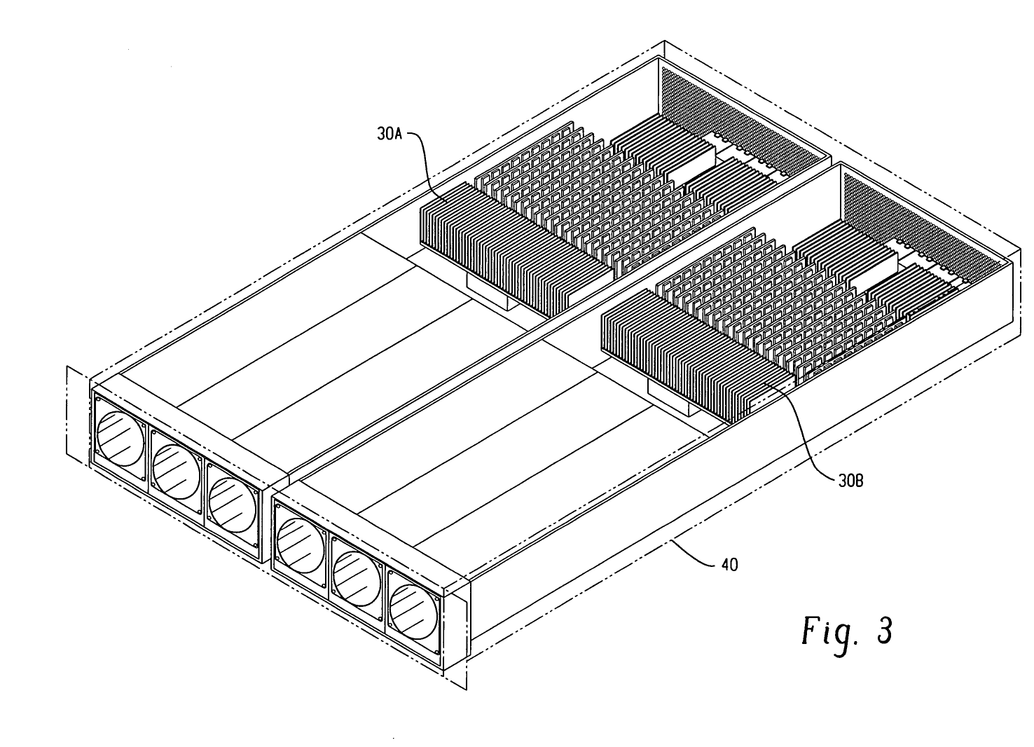

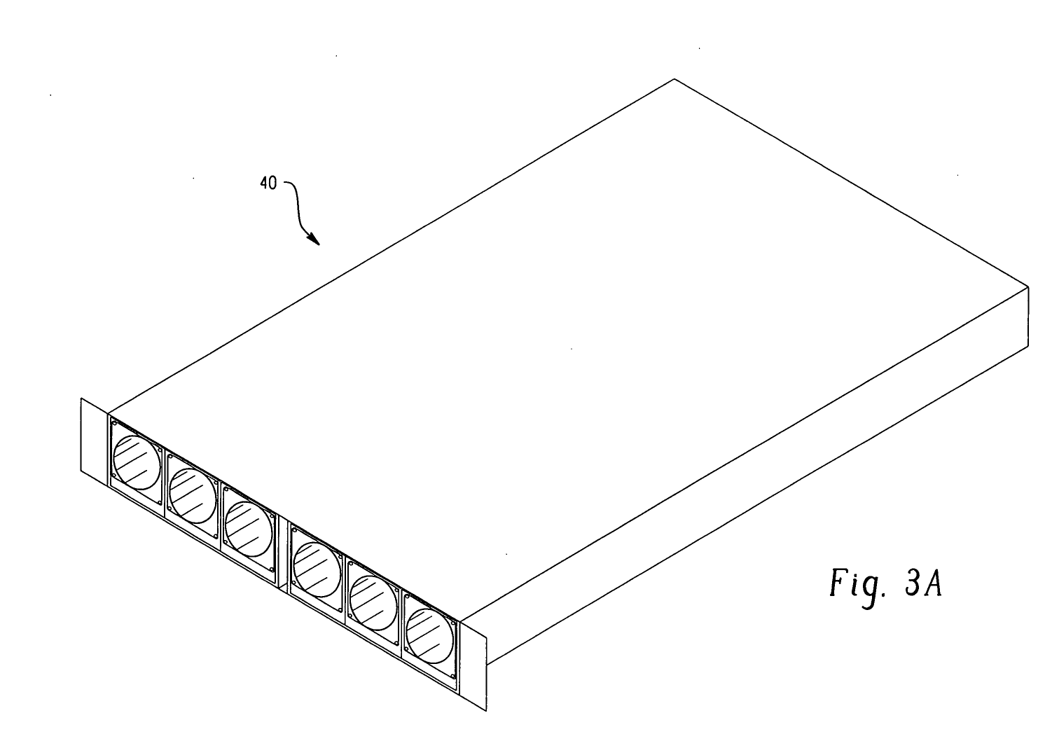

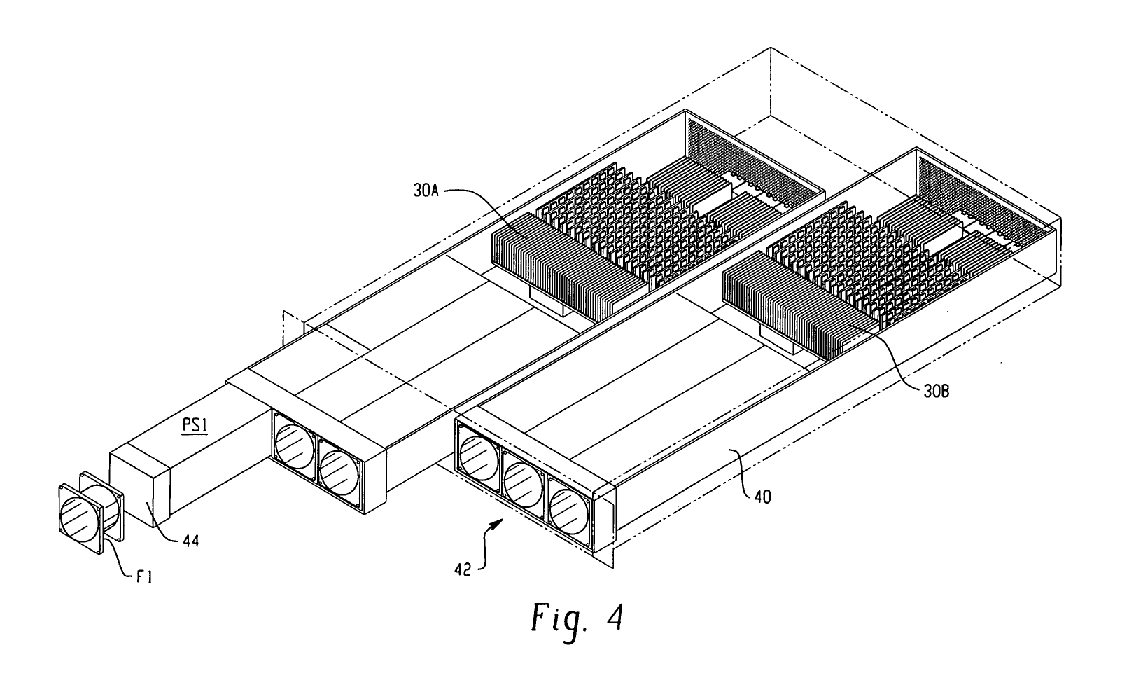

As part of the present embodiment, two (2) cell modules 30A and 30B may be disposed side by side in a standard 2U rack enclosure 40 as shown in the isometric perspective illustration of FIG. 3. A fully enclosed rack enclosure 40 is shown in FIG. 3A. Each of the cell modules 30A and 30B may be slide into the rack enclosure 40 through a front opening 42 as illustrated in the isometric perspective view of FIG. 4 for convenient assembly and replacement, if the need should arise. Thus, if a design change should arise during the development cycle or after the system has been shipped, a current cell module may be conveniently replaced with a new cell module by merely sliding the current cell module out from the rack enclosure and sliding the new module into the corresponding slot thereof.

In addition, as noted herein above, each of the power supply modules, as exemplified by module PS1 in FIG. 4, may be inserted into its cell module 30, by sliding it into the corresponding slot from the front of each cell module 30 for assembly. Likewise, a power supply module may be replaced by sliding the current module out of its corresponding slot and sliding a new module into the same slot. The present embodiment also provides a convenient assembly or replacement of the associated fans of the power supply modules. By way of example, the illustration of FIG. 4 depicts the insertion of the fan F1 into or the removal of the fan F1 from a frontal compartment 44 of the power module PS1.

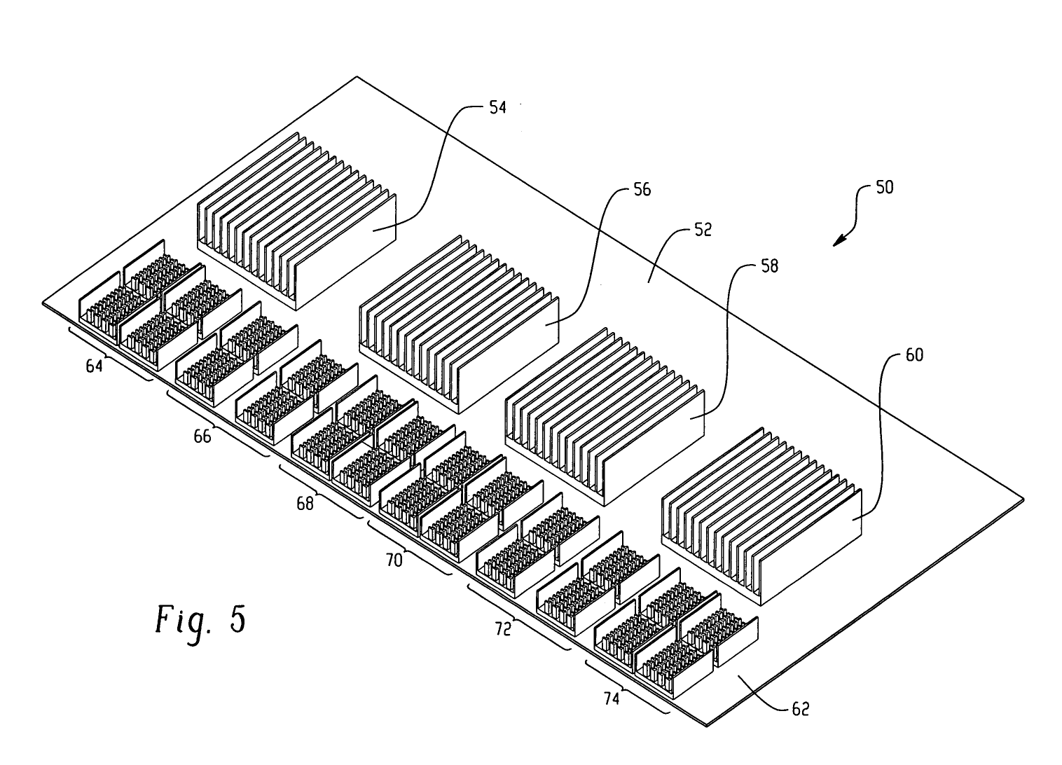

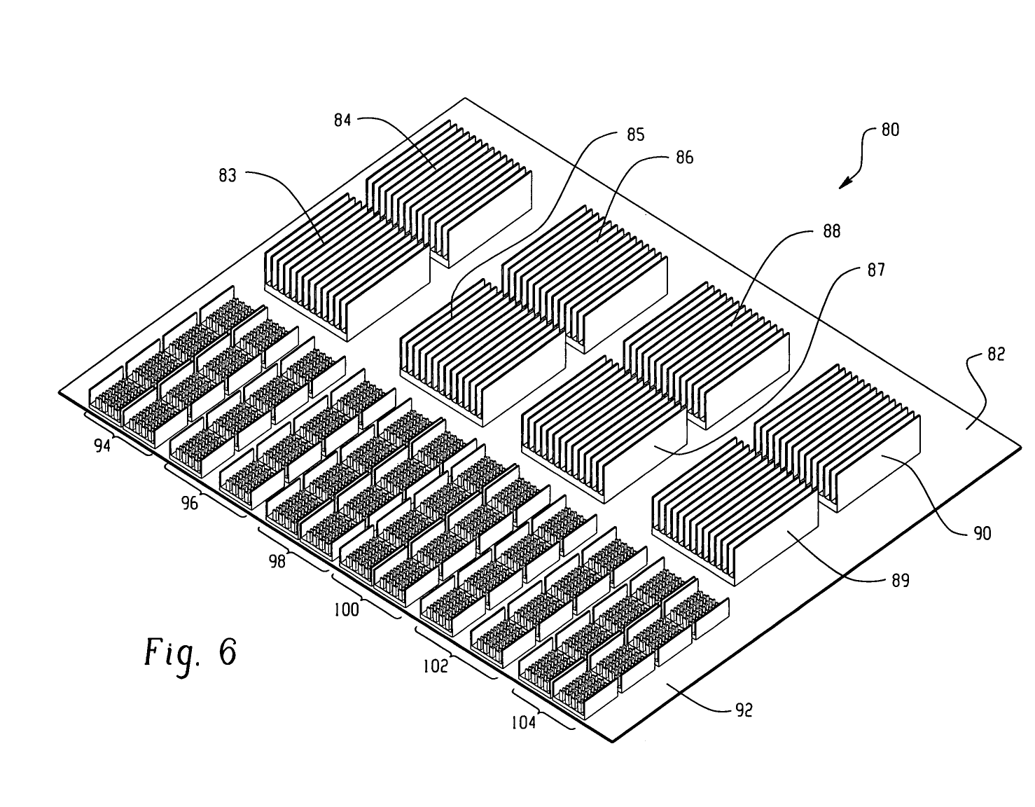

Also, as part of the present embodiment is a link router or switch module. Exemplary half and full link router modules are depicted in FIGS. 5 and 6, respectively. Referring first to FIG. 5, the exemplary half link router module 50 comprises a PC board 52 on which is mounted a plurality of cross-bar or X-bar ICs 54, 56, 58, and 60 which may be application specific integrated circuits (ASICs), for example. Each of the cross-bar ICs may include an associated heat sink. The plurality of cross-bar ICs may be programmed to perform the desired switching of information among the various cell modules and IO devices coupled to the system. Thus, each link router module 50 may be programmed for a specific design architecture and performance.

Also mounted on the board 52 at a frontal region 62 is a plurality of cable connectors. In the present embodiment, the cable connectors of the half link router 50 are mounted in board region 62 in two (2) rows of twelve (12) connectors and grouped into six (6) sets of four (4) adjacent connectors 64, 66, 68, 70, 72 and 74. Sets 64, 68, 70 and 74 may be assigned for cable connections to cell modules, and sets 66 and 72 may be assigned for cable connections to IO devices, for example. The PC board will have etched routing for interconnecting the cable connectors to the cross-bar ICs. In the present embodiment, the cable connectors may be of the high speed type manufactured by Tyco, for example. These particular cable connectors may have as many as 40 differential pairs of pins for cable connection, but more than likely will have 8 to 16 differential pairs of pins as will become better understood from the description found herein below.

Referring now to FIG. 6, the exemplary full link router module 80 comprises a PC board 82 which may have double the surface area as the half link router board 52 described above. On the board 82 may be mounted a plurality of cross-bar or X-bar ICs 83-90 which may be twice as many as the half link router 50, for example. The plurality of cross-bar ICs 83-90, which also may be ASICs, may include associated heat sinks and may be programmed to perform the desired switching of information among the various cell modules and IO devices coupled to the system in the same manner as the half link router 50, but with a much larger capacity. Thus, each full link router module 80 may be programmed for a specific design architecture and performance.

Also mounted on the board 82 at a frontal region 92 is a plurality of cable connectors in much the same manner as the half link router board except that the cable connectors of the full link router 80 are mounted in board region 92 in four (4) rows of twelve (12) connectors and grouped into six (6) sets of eight (8) adjacent connectors 94, 96, 98, 100, 102 and 104. Sets 94, 98, 100 and 104 may be assigned for cable connections to cell modules, and sets 96 and 102 may be assigned for cable connections to IO devices, for example. The PC board will also have etched routing for interconnecting the cable connectors to the cross-bar ICs. The cable connectors of the full link router may be of the same type as that of the half link router, each connector having as many as 40 differential pairs of pins for cable connection as will become better understood from the description found herein below.

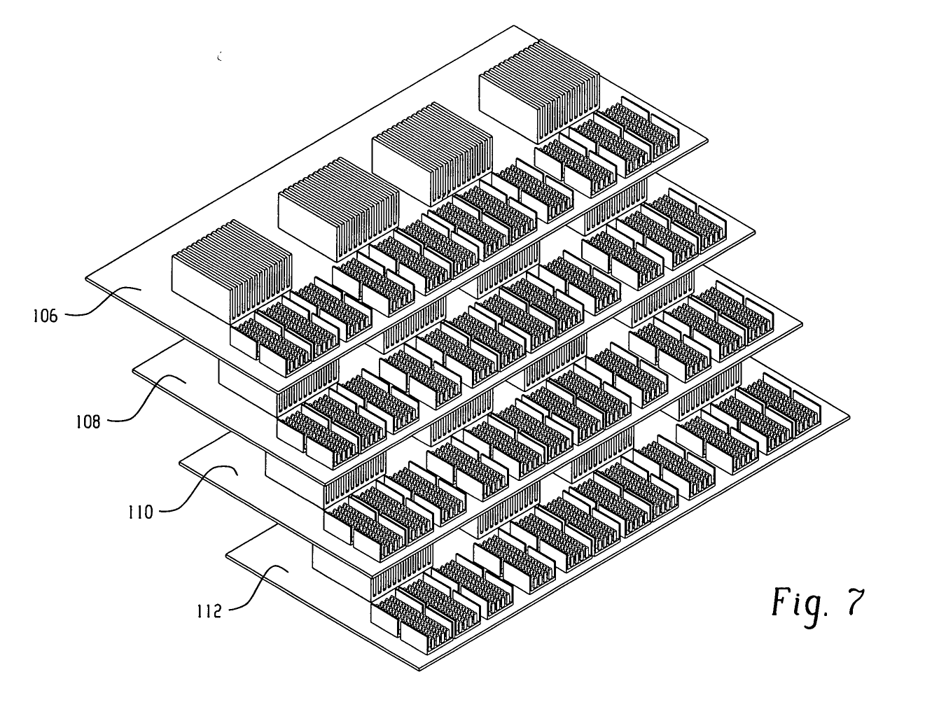

FIG. 7 is an isometric perspective illustration of a plurality of half link router boards 106, 108, 110 and 112 in an exemplary configuration as they would be assembled in the present architecture embodiment. While half link router boards are used in the present example, it is understood that full link router boards or a combination of the two may be used just as well. The plurality of boards 106, 108, 110 and 112 may be configured in horizontal planes one over the other in a stair-step manner so that the cable connectors of each board are exposed for cable connection. While the exemplary configuration of link router boards are shown as having the components thereof facing up for mounting on the bottom of a cabinet, it is understood that they may be also configured with their components facing down for mounting on the top of a cabinet as will become more evident from the following description.

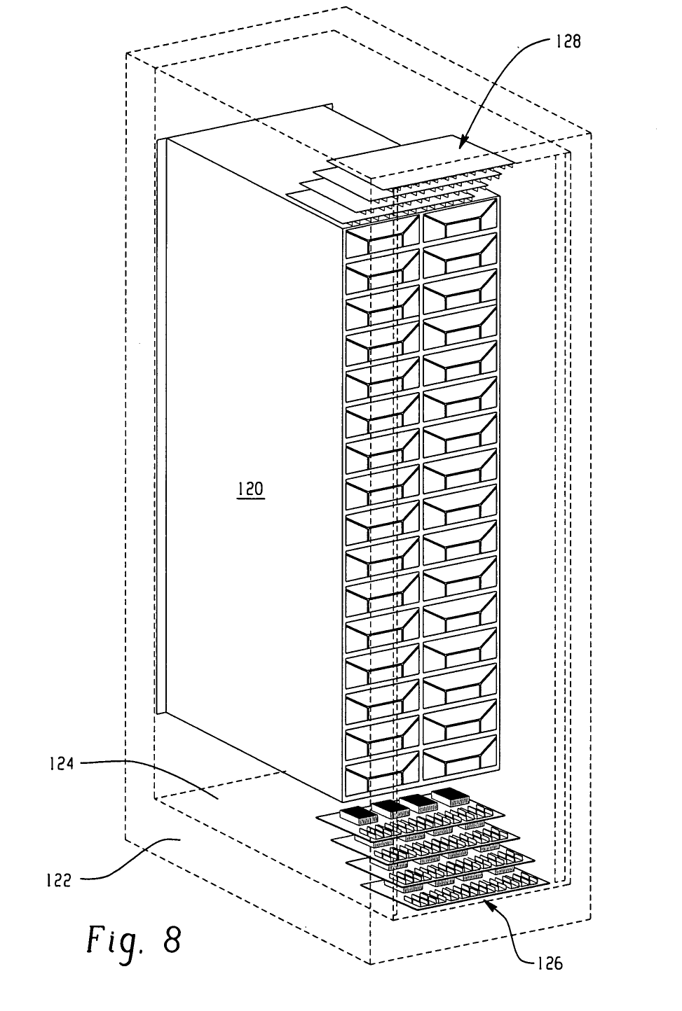

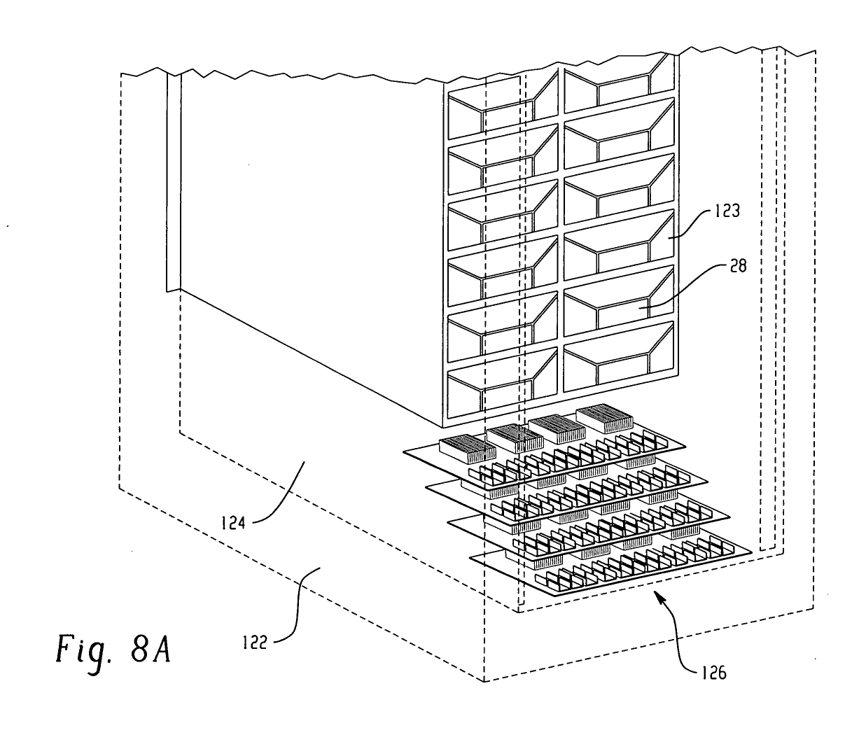

FIG. 8 is a “see through” isometric perspective rear view illustration of an exemplary multi-processor system architecture suitable for embodying one aspect of the present invention. The exemplary system architecture of FIG. 8 includes a 19 inch cabinet rack 120 mounted in an electronics cabinet 122. FIG. 8A is an expanded “see through” isometric perspective illustration of the bottom portion of cabinet 122.

Referring to FIGS. 8 and 8A, the rack 120 of the present example may be capable of holding 2U enclosures 123 of the type described herein above in connection with FIGS. 3 and 4 on 16 levels, rendering a rack of 32 processing cell modules. Each of the 32 cell modules have their set of connectors 28 exposed for cable connection. The rack 120 may be mounted in a substructure 124 of cabinet 122. The substructure 124 may include space at the bottom of rack 120 in which to mount a plurality of link router boards 126 which are configured in much the same manner as described in connection with FIG. 7 above. The substructure 124 may also include space at the top of rack 120 in which to mount a plurality of link router boards 128 which are configured in an upside-down manner as that described in connection with FIG. 7. In both configurations of link router boards, the cable connectors are left exposed for cable connection.

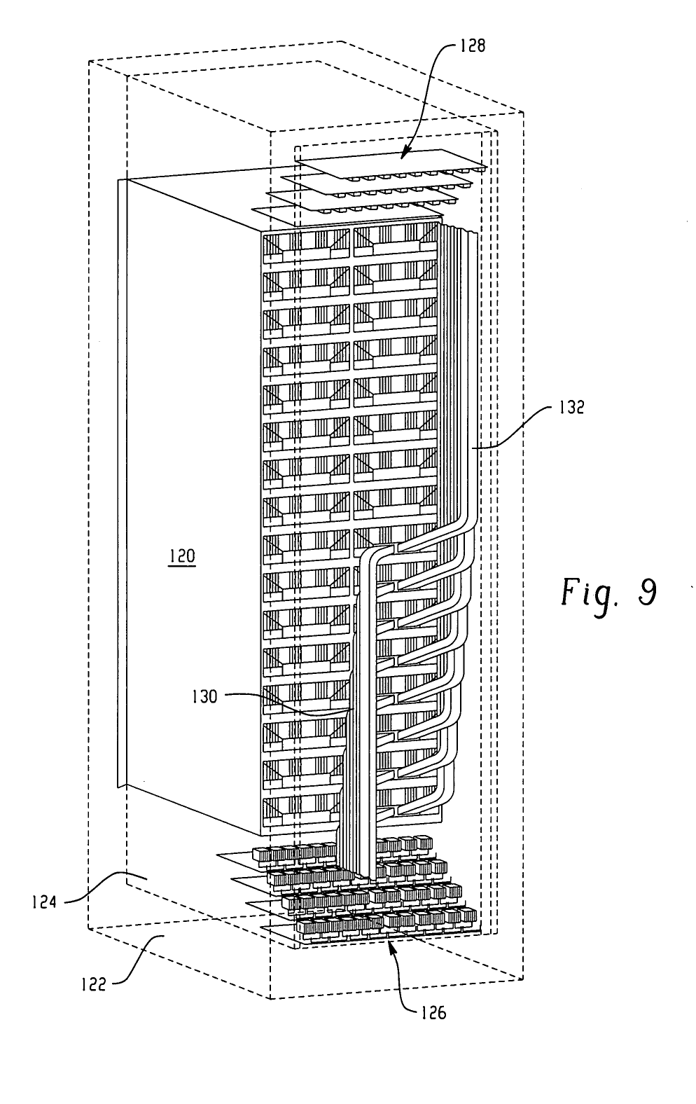

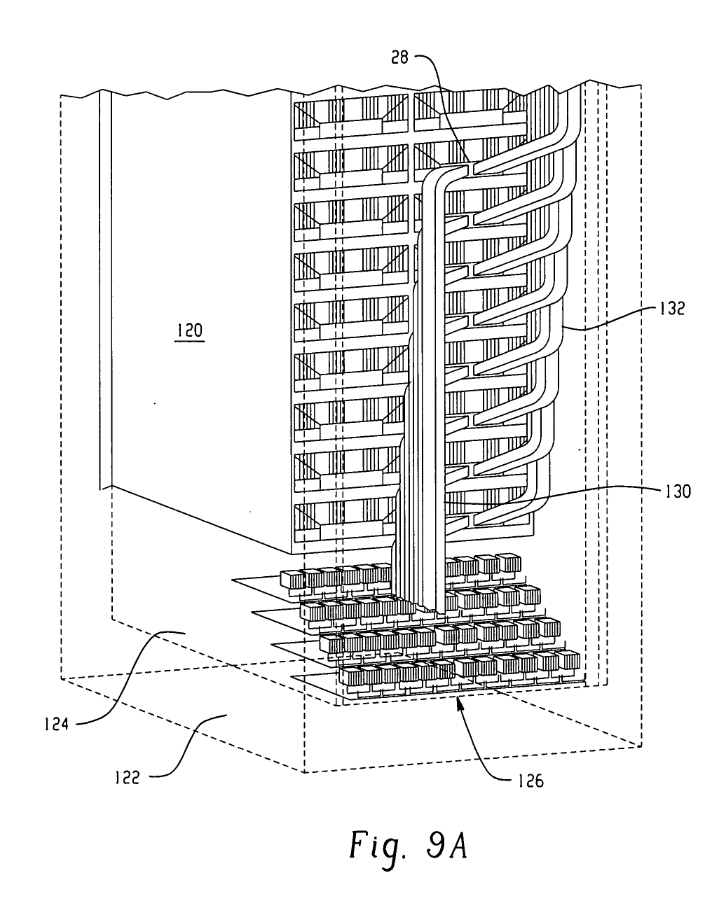

FIG. 9 is a “see through” isometric perspective rear view illustrations of the exemplary system architecture described in connection with FIG. 8 showing cables interconnecting the link router boards with the cell modules of the 2U enclosures. FIG. 9A is an expanded view of the cabinet bottom much the same as described for FIG. 8 except including the cable connections. The reference numerals of common system components between FIGS. 8 and 9 will remain the same with no further description thereof. Referring to FIGS. 9 and 9A, a set of cables 130 having the proper mating connectors at both ends are used to interconnect some of the set of connectors 28 of the cell modules of rack 120 with the connectors of the link router boards 126 mounted at the bottom of the substructure 124. A similar set of cables 132 are used to interconnect others of the set of connectors 28 of the cell modules of rack 120 with the link router boards 128 mounted at the top of the substructure 124. Note that the system architecture of the present embodiment is without any backplane or midplanes.

The cables of sets 130 and 132 may be of a Peripheral Component Interconnect Express (PCIE) industry standard type and may contain on the order of eight (8) to sixteen (16) differential wire pairs, for example. In the present embodiment, each cable of the sets 130 and 132 includes one or more first type mating connectors at one end for connecting to designated Tyco cable connectors of the link router boards and one or more second type mating connectors at the other end for connecting to designated HMZD connectors of the cell modules. Note that the cable sets 130 and 132 of the present embodiment replace the interconnect functions of the backplanes and midplanes used in current system architectures. Other cables may be used to connect the link router boards to IO devices.

The present system architecture as exemplified by the foregoing described embodiment, is more flexible than current system architectures in that there is no permanently mounted backplane or midplanes and the various system components are conveniently replaceable. In the present embodiment, all of the system components and IO devices may be interconnected by cables. Thus, the system architecture may be conveniently assembled and changed during system development or after product shipment. If a different cell module is desired, the old cell unit may be slid out from its 2U enclosure and a new one slid in and connected. If a new cable connection is desired, the old cable or cables may be disconnected and new ones connected in place thereof. Even the link router boards may be conveniently replaced in the present embodiment. Moreover, different switch board designs along with different IO configurations may be used with the same cell module design. Accordingly, the present system architecture may be conveniently rearranged, added to or deleted from as the product specification changes or to adjust to differing application needs.

The present system architecture enables low entry point and pay-as-you-go costs. For example, the cooling and power costs are individually distributed with the cell modules 30 unlike a large integrated system that has one common infrastructure. In addition, the cabled module approach enables a variety of system types. For instance, small systems may use zero, one or two router modules since some of the IO devices may be directly attached by cable to the cell modules for reduced cost. The router modules may be customized to match the desired system size. Only one switch may be included on a router board with a limited number of connectors to target mid-sized systems. Large systems may be may be constructed with multiple cabinet racks of cell modules cabled together.

Further, in smaller systems, the full containment of power and cooling of a cell module enables mixing the cell modules with IO and other devices and peripherals in a common standard cabinet rack. Still further, the router boards have connections between the switches that enable full connectivity between each and every cable which allows systems to be fully connected. Further yet, the present system architecture allows cell and router modules to be swapped out for future system upgrades as newer technology becomes available.

While the present invention has been described herein above in connection with one or more embodiments, it is understood that these embodiments were presented merely by way of example without any intention of limiting the present invention. Accordingly, the present invention should not be limited in any way by such embodiments, but rather construed in breadth and broad scope in accordance with the recitation of the claims appended hereto.

What is claimed is:

1. A multi-processor system architecture comprising:
a cabinet;
a plurality of processor cell modules disposed within said cabinet;
a plurality of link router modules disposed within said cabinet; and
a plurality of cables connecting said plurality of processor cell modules through said plurality of link router modules.

2. The system architecture of claim 1 wherein each cell module of the plurality including a set of first cable connectors; wherein each link router module of the plurality including a set of second cable connectors; and wherein the plurality of cables interconnecting the first cable connectors to the second cable connectors.

3. The system architecture of claim 1 wherein each cell module comprises a housing containing:
at least one processor cell unit;
at least one power supply unit for supplying power to said at least one processor cell unit; and
at least one forced air cooling unit.

4. The system architecture of claim 3 wherein the housing contains a plurality of power supply units which are insertable into and removable from corresponding slots in the housing.

5. The system architecture of claim 3 wherein each power supply unit includes a compartment for holding a forced air cooling unit, the forced air cooling unit being insertable into and removable from said compartment.

6. The system architecture of claim 3 including at least one rack enclosure for mounting within the cabinet; and wherein a plurality of cell module housings are disposed side by side within each rack enclosure.

7. The system architecture of claim 3 including a plurality of rack enclosures being stack mounted within the cabinet; and wherein a plurality of cell module housings are disposed side by side within each rack enclosure.

8. The system architecture of claim 1 wherein each link router module of the plurality comprises a circuit board including: a plurality of cross-bar integrated circuits mounted to a first region of said board; a plurality of cable connectors mounted to a second region of said board; and routing interconnecting the cable connectors to the cross-bar integrated circuits.

9. The system architecture of claim 8 wherein the link router circuit boards are mounted within the cabinet in a stair-step configuration to expose the second regions thereof for cable connection to the cable connectors of the second regions.

10. The system architecture of claim 8 wherein the plurality of cable connectors of each link router circuit board comprise: first cable connectors for connecting to processor cell modules; and second cable connectors for connecting to input/output devices; and wherein the plurality of cables connect said first cable connectors to the plurality of processor cell modules.

11. The system architecture of claim 1 wherein the link router modules are programmable to accommodate different link router configurations of the system architecture.

12. The system architecture of claim 1 wherein the processor cell modules are insertable into and removable from corresponding positions within the cabinet so that each processor cell module is replaceable with another processor cell module.

13. The system architecture of claim 1 wherein the link router modules are insertable into and removable from corresponding positions within the cabinet so that each link router module is replaceable with another link router module.

14. The system architecture of claim 1 wherein the cables of the plurality of cables are connectable to and disconnectable from the processor cell modules and link routers so that each cable is replaceable with another cable.

15. A processor cell module for a multi-processor system comprising:
a housing containing:
at least one processor cell unit;
a plurality of power supply units insertable into and removable from corresponding slots in the housing, at least one power supply unit of said plurality for supplying power to said at least one processor cell unit;
at least one forced air cooling unit; and
a set of cable connectors for cable coupling to other processor cell modules.

16. The module of claim 15 wherein each power supply unit includes a compartment for holding a forced air cooling unit, the forced air cooling unit being insertable into and removable from said compartment.

17. A link router module for a multi-processor system comprising:
a circuit board including:
a plurality of cross-bar integrated circuits mounted to a first region of said board;
a plurality of cable connectors mounted to a second region of said board; and
routing interconnecting the cable connectors to the cross-bar integrated circuits.

18. The module of claim 17 wherein the plurality of cable connectors comprise: first cable connectors for connecting to processor cell modules; and second cable connectors for connecting to input/output devices.

19. The module of claim 17 wherein the cross-bar integrated circuits are programmable to accommodate different link router configurations.
